(19) United States
(12) Patent Application Publication
(10) Pub. No.: US 2002/0031150 A1
(43) Pub. Date: Mar. 14, 2002

(54) Semiconductor laser module

(75) Inventors: Takeshi Aikiyo, Tokyo (JP); Toshio Kimura, Tokyo (JP); Shinichiro Iizuka, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Chiyoda-ku (JP)

(21) Appl. No.: 09/822,345

(22) Filed: Apr. 2, 2001

(30) Foreign Application Priority Data
Mar. 31, 2000 (JP) 2000-096940

(51) Int. Cl. H01S 3/04; H01S 5/00

(52) U.S. Cl. 372/36; 372/43

(57) ABSTRACT

The invention provides a semiconductor laser module of high output in which the radiating property of heat generated from a semiconductor laser element is high, and power consumption is small. In this semiconductor laser module, a base is arranged on a Peltier module, and has a basic portion having a face fixed to the Peltier module and a stem supporting portion rising on the basic portion. The base is formed by a material having a preferable coefficient of thermal conductivity. An internal module has the semiconductor laser element attached to a stem, an optical fiber for receiving a laser beam, and a member such as a lens for coupling the laser beam to the optical fiber. When this internal module is fixed to the base, the stem comes in contact with a stem supporting face of the stem supporting portion, and is fixed to the stem supporting face. The heat generated from the semiconductor laser element is directly transmitted from the stem to the base without passing a cap attached to the stem.

### BACKGROUND OF THE INVENTION

A semiconductor laser is used in large quantities as a signal light source and a pumping light source of an optical fiber amplifier in optical communication. When the semiconductor laser is used as the signal light source and the pumping light source in the optical communication, the semiconductor laser is used as a semiconductor laser module in many cases. The semiconductor laser module is a device in which a laser beam from the semiconductor laser is optically coupled to an optical fiber.

FIG. 8 shows one example of a conventional semiconductor laser module. In FIG. 8, a semiconductor laser element 11 is fixedly attached to a columnar stem 14 through a heat sink 12 and a copper block 13. A cylindrical cap 15 made of stainless steel is fixed to a circumferential edge portion of the stem 14. A translucent window 16 for transmitting light emitted from the semiconductor laser element 11 is arranged in the cap 15.

The stem 14 and the cap 15 are fixed by resistance welding (projection welding). The stem 14 is, for example, formed of iron or an iron-nickel alloy, etc. so as to facilitate the welding. A semiconductor element 11 is accommodated in a hermetic space defined by a stem 14 and a cap 15 covering the stem 14 to form a semiconductor laser unit 10.

A lens holder 20 having a lens 21 is continuously connected to this semiconductor laser unit 10, and a slide ring 23 is fixed to this lens holder 20. A protecting sleeve 22 made of stainless steel is arranged in the slide ring 23, and an optical fiber 24 is fixedly inserted into this protecting sleeve 22. The optical fiber 24 receives a laser beam emitted from the semiconductor laser element 11. The lens 21 interposed between the semiconductor laser element 11 and the optical fiber 24 is an optical coupling means for optically coupling the laser beam emitted from the semiconductor laser element 11 to the optical fiber 24.

Namely, the laser beam emitted from the semiconductor laser element 11 is converged by the lens 21, and is incident to the optical fiber 24. Therefore, in the semiconductor laser module of this kind, the optical fiber 24 is aligned and fixed in a position for maximizing its incident light intensity.

An internal module 30 is composed of the semiconductor laser element unit 10, the lens 21, the lens holder 20, the slide ring 23, the protecting sleeve 22 and the optical fiber 24. The internal module 30 is fixedly supported by a base 31 having a flat plate shape with a lower portion side of the cap 15 (a drum portion of the internal module 30) coming in contact with the base 31. Since the cap 15 is formed in a cylindrical shape as mentioned above, the cap 15 and the base 31 come in contact each other along a line.

A Peltier module 32 which functions to cool the internal module 30 is arranged on a lower portion side of the base 31. The Peltier module 32 is connected to an unillustrated external control circuit. A thermistor (temperature sensor) 34 for detecting a temperature of the semiconductor laser element 11 is arranged in a central portion of the base 31. The thermistor 34 is connected to the external control circuit of the Peltier module 32, and temperature information sensed by the thermistor 34 is transmitted to this external control circuit.

The internal module 30, the base 31 and the Peltier module 32 are accommodated in to a package 33. The optical fiber 24 is guided to the package exterior through an optical fiber guide hole 50 formed in a side wall portion 33c of the package 33. A boot 49 is arranged in an external guide portion of this optical fiber 24. An outer circumferential side of the optical fiber 24 is covered with the boot 49 to protect the optical fiber 24. Resin 25 is filled in the optical fiber guide hole 50, thereby fixing the optical fiber 24 and sealing the optical fiber guide-hole 50.

The package 33 has a bottom plate portion 33a, the side wall portion 33c and a cover portion 33b.

As mentioned above, the internal module 30, the base 31 and the Peltier module 32 are fixedly accommodated, with the bottom plate portion 33a and the side wall portion 33c being fixed in advance, and thereafter, the cover portion 33b is put in place and a circumferential edge portion thereof is sealed. The interior of the package 33 is set to hermetic state by this sealing.

In the semiconductor laser module having the above construction, when a semiconductor laser element is operated by feeding an electric current from the exterior a laser beam is emitted from the semiconductor, laser element 11. This laser beam is converged by the lens 21 as mentioned above, and is incident to an end face 24a of the optical fiber 24. The laser beam is wave-guided by the optical fiber 24, and is used for desired uses.

When the semiconductor laser element 11 is operated as mentioned above, the heat generated from the semiconductor laser element 11 is discharged to the exterior of the semiconductor laser module sequentially through the heat sink 12, the element fixing block 13, the stem 14, the cap 15, the base 31, the Peltier module 32 and the bottom plate portion 33a of the package 33. The optical output and the wavelength of the semiconductor laser element 11 generally change with a change in temperature. Therefore, it is necessary to keep the temperature of the semiconductor laser element 11 constant. An electric current flowing through the Peltier module 32 is adjusted by the external control circuit such that the temperature sensed by the thermistor 34 becomes constant.

### SUMMARY OF THE INVENTION

The present invention provides a semiconductor laser module having the following construction in one aspect. Namely, one aspect of the invention resides in a semiconductor laser module comprising:

a package;

a Peltier module fixed to a bottom face wall of said package and accommodated into the package;

a base fixed onto said Peltier module; and

an internal module supported by said base;

said internal module having:

a stem;

a semiconductor laser element attached to said stem;

an optical fiber for guiding a laser beam emitted from said semiconductor laser element to the exterior of said package; and

optical coupling means for optically coupling the laser beam emitted from said semiconductor laser element to said optical fiber;

wherein said stem in said internal module comes in face contact with said base and is fixed to the base.

### BRIEF DESCRIPTION OF THE DRAWINGS

Exemplary embodiments of the invention will now be described in conjunction with drawings, in which:

FIG. 1 is a view for explaining the construction of a semiconductor laser module in a first embodiment of the present invention;

FIG. 2 is a cross-sectional view taken along line A-A′ of FIG. 1;

FIG. 3 is a cross-sectional view for explaining the construction of a semiconductor laser module in a second embodiment of the present invention;

FIG. 4 is a cross-sectional view for explaining the construction of a semiconductor laser module in a third embodiment of the present invention;

FIG. 5 is a cross-sectional view for explaining the construction of a semiconductor laser module in another embodiment of the invention;

FIG. 6 is a cross-sectional view for explaining the construction of a semiconductor laser module in still another embodiment of the invention;

FIG. 7A is a cross-sectional view for explaining the construction of a semiconductor laser module in still another embodiment of the invention;

FIG. 7B is a view for explaining the construction of a stem section applied to the semiconductor laser module shown in FIG. 7A;

FIG. 8 is a cross-sectional view for explaining one example of a conventional semiconductor laser module.

### DESCRIPTION OF THE PREFERRED EMBODIMENTS

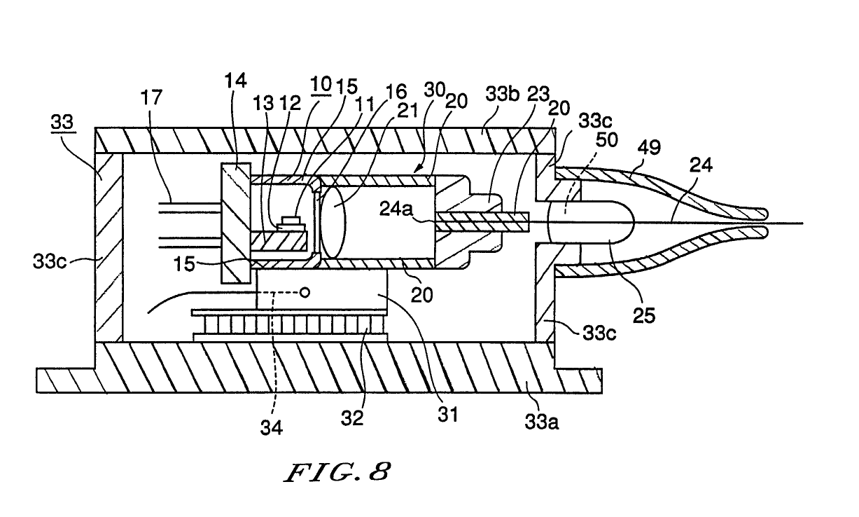

In the conventional semiconductor laser module shown in FIG. 8, heat generated when operating the semiconductor laser element 11 is discharged to the exterior through the heat sink 12, the element fixing block 13, the stem 14, the cap 15, the base 31, the Peltier module 32 and the bottom plate portion 33a of the package 33 as mentioned above. Accordingly, the heat from the semiconductor laser element 11 passes many members until the heat is transmitted to the base 31.

In particular, the cap 15 is thinly formed, and the cap 15 and the base 31 come each other only along a line in their contact portions so that heat transmitting efficiency from the cap 15 to the base 31 is poor.

Therefore, in the conventional semiconductor laser module, heat radiating efficiency is poor when the heat generated from the semiconductor laser element 11 is discharged to the exterior of the semiconductor laser module through the above path. Further, the temperature sensed by the thermistor 34 is lower than the actual temperature of the semiconductor laser element 11. Therefore, it is difficult to precisely control an operation of the Peltier module 32 on the basis of this sensed temperature.

Inadequate control of the peltier module 32 lowers the efficiency of the semiconductor laser element 11 and makes it impossible to obtain a high optical output. Then, it becomes necessary to flow a larger electric current so as to obtain a prescribed light output from the semiconductor laser element 11 and the problem of an increase in power consumption of the semiconductor laser element 11 arises. Further, a larger electric current flowing through the semiconductor laser element 11, increases the amount of heat generated at the semiconductor laser element 11 and results in an increase in power consumption of the Peltier module 32 for cooling this generated heat.

In particular, with the recent increase in the capacity of optical communication there is an increased expectance for the semiconductor laser element 11 for pumping an erbium doped optical fiber in an oscillation wavelength band of 1480 nm as a semiconductor laser element 11 of high output. However, since the amount of heat generated by such an element is so large that, when the semiconductor laser element of the kind is used, the above-mentioned problem of an increase in power consumption of the semiconductor laser element 11 and of the Peltier module 32 arising from the poor transmission of the heat generated at the semiconductor element 11 becomes a very serious problem.

The invention provides a semiconductor laser module in which heat generated from the semiconductor laser element can be efficiently radiated, and the temperature of the semiconductor laser element can be precisely controlled by the Peltier module, and power consumption is small.

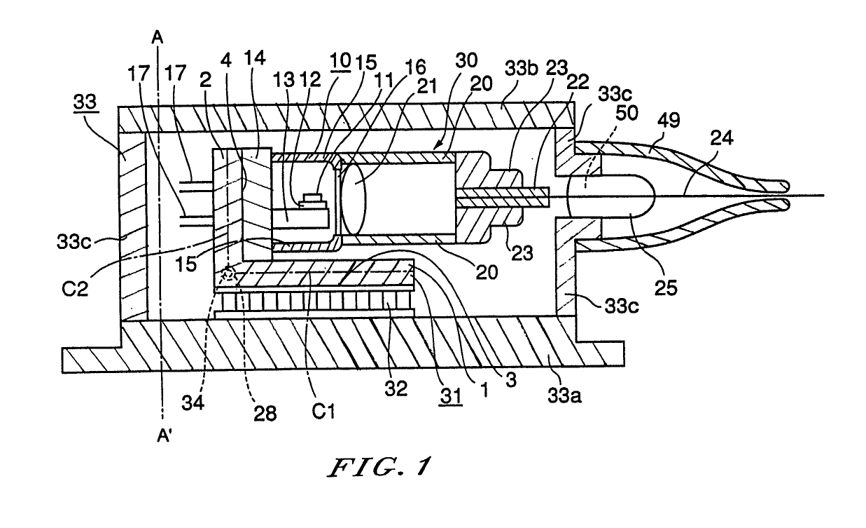

Each of concrete embodiments of the invention will next be explained on the basis of the drawings. In the following explanation of each embodiment, portions common to those in the conventional example explained with reference to FIG. 8 are designated by the same reference numerals, and their overlapped explanations thereof are omitted or simplified. FIG. 1 is a cross-sectional view showing the construction of a semiconductor laser module in a first embodiment of the present invention.

As shown in FIG. 1, the semiconductor laser module in the first embodiment has a construction approximately similar to that in the conventional example shown in FIG. 8. The first embodiment differs from the conventional example in that a base 31 is formed in an L-shape in section having a basic portion 1 having a face 3 to be fixed to a Peltier module 32, and a stem supporting portion 2 approximately upright on one end side of the basic portion 1 thereon, wherein at least a stem 14 of an internal module 30 comes in face contact with the base 31 and is fixed to this base 31.

For example, the base 31 is made of by a material having a preferable heat conducting property such as copper, a copper tungsten alloy, etc. to ensure a heat radiating property. The face 3 of the basic portion 1 of the base 31 is joined to the Peltier module 32 by solder, etc. in one example. A bottom face of the stem 14 (a face opposite to an attaching side of the semiconductor laser element 11) is fixed to a stem supporting face 4 of the stem supporting portion 2 by e.g., an adhesive or solder. In the first embodiment, the stem supporting face 4 is perpendicular to the basic portion 1.

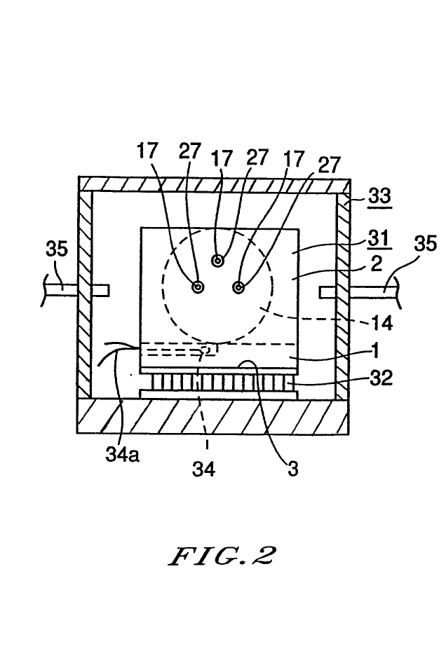

FIG. 2 is a view in which a right-hand side portion of FIG. 1 is seen from an A-A′ face of FIG. 1. As shown in FIGS. 1 and 2, a thermistor insertion hole 28 is formed in the base 31 on a path of heat generated from the semiconductor laser element 11 and flowing onto a Peltier module side through the base 31. In the first embodiment, this thermistor insertion hole 28 is arranged in an intersection position of a central axis C1 of the basic portion 1 of the base 31 and a central axis C2 of the stem supporting portion 2 or in the vicinity of this position. A thermistor (temperature sensor), 34 is arranged in the thermistor insertion hole 28, and a lead wire 34a of the thermistor 34 is drawn out to the base exterior from the thermistor insertion hole 28.

As shown in FIG. 2, a plurality of lead insertion holes 27 are formed in the stem supporting portion 2. A lead 17 (see FIG. 1) drawn out of the stem 14 is inserted into the lead insertion hole 27. The lead 17 electrically connects the semiconductor laser element 11 and an unillustrated monitor photodiode fixed inside the semiconductor laser unit 10 to an external circuit. One end side of the lead 17 is guided to the interior of the semiconductor laser unit 10, and is connected to the semiconductor laser element 11 and the monitor photodiode through e.g., an unillustrated gold wire.

As shown in FIG. 2, a plurality of leads 35 (not shown in FIG. 1) are respectively arranged in both side wall portions 33c of a package 33. Each of the lead 17 and the lead wire 34a of the thermistor 34 is connected to the corresponding lead 35 in a set position. In the drawings used in the explanation of this specification, an arranging state of the lead 35, a connecting state of the lead 35 and the lead 17, and a connecting state of the lead 35 and the lead wire 34a are omitted to simplify the drawings.

The first embodiment is constructed as mentioned above. In the first embodiment, similar to the semiconductor laser module in the conventional example, the semiconductor laser element 11 is operated, and a laser beam from the semiconductor laser element 11 is received by an optical fiber 24 through a lens 21. In the first embodiment, heat generated by operating the semiconductor laser element 11 is transmitted to the stem supporting portion 2 of the base 31 sequentially through a heat sink 12, an element fixing block 13 and the stem 14, and is also transmitted from the basic portion 1 of the base 31 to the Peltier module 32.

Thus, in the first embodiment, the heat generated from the semiconductor laser element 11 is directly transmitted from the stem 14 to the base 31 as mentioned above without passing a thin cap 15 attached to the stem 14. Therefore, a heat conducting property from the semiconductor laser element 11 to the base 31 can be improved. In particular, in the first embodiment, an entire bottom face of the stem 14 comes in face contact with the stem supporting face 4 of the stem supporting portion 2. Therefore, the heat from the semiconductor laser element 11 can be very efficiently transmitted to the base 31.

In the first embodiment, since the base 31 is formed of a material having a high thermal conductivity such as copper, a copper tungsten alloy, etc. the heat conducting property from the base 31 to the Peltier module 32 can be also improved. The heat radiating property from the Peltier module 32 to the exterior through a bottom face wall of the package 33 can be also greatly improved in comparison with the conventional example.

Accordingly, in accordance with the first embodiment, a high output can be obtained from the semiconductor laser element 11 without reducing efficiency of the semiconductor laser element 11. Further, the temperature of the semiconductor laser element can be precisely controlled by the Peltier module 32 fixed to the base 31. Therefore, it is also possible to dissolve the problem of the conventional example in which power consumption of the semiconductor laser element 11 and of the Peltier module 32 are increased because no precise temperature control using the Peltier module 32 is performed. Thus, the semiconductor laser module having small power consumption can be obtained.

Further, in accordance with the first embodiment, since the thermistor insertion hole 28 is formed on a path of the heat generated from the semiconductor laser element 11 and flowing onto a side of the Peltier module 32 through the base 31 and the thermistor 34 is inserted into this thermistor insertion hole 28, the temperature of the semiconductor laser element 11 can be accurately detected by the thermistor 34.

In particular, while in the conventional example, the thermistor 34 is arranged in a position passing the cap 15 of poor heat transmitting efficiency and therefore it is difficult for a thermistor 34 to rapidly follow a change in temperature of the semiconductor laser element 11 in the first embodiment, since the thermistor 34 is arranged in the vicinity of an intersection point of a central axis C1 of the basic portion 1 of the base 31 and a central axis C2 of the stem supporting portion 2, and is located in a position near the semiconductor laser element (a position nearer to the semiconductor laser element in comparison with the center of the basic portion 1 of the base 31) on the heat path, the thermistor 34 can rapidly follow can precisely sense the change in temperature of the semiconductor laser element 11.

Accordingly, in accordance with the first embodiment, the temperature control of the Peltier module 32 based on the sensed temperature of the thermistor 34 can be very rapidly performed in accordance with the change in temperature of the semiconductor laser element 11 so that response in the temperature detection of the semiconductor laser element 11 and in the temperature can be improved very much. Therefore, it is possible to improve the stabilities of a light output and a wavelength of the semiconductor laser element 11 making sure that power consumption of the semiconductor laser element 11 and of the Peltier module 32 can be reduced further.

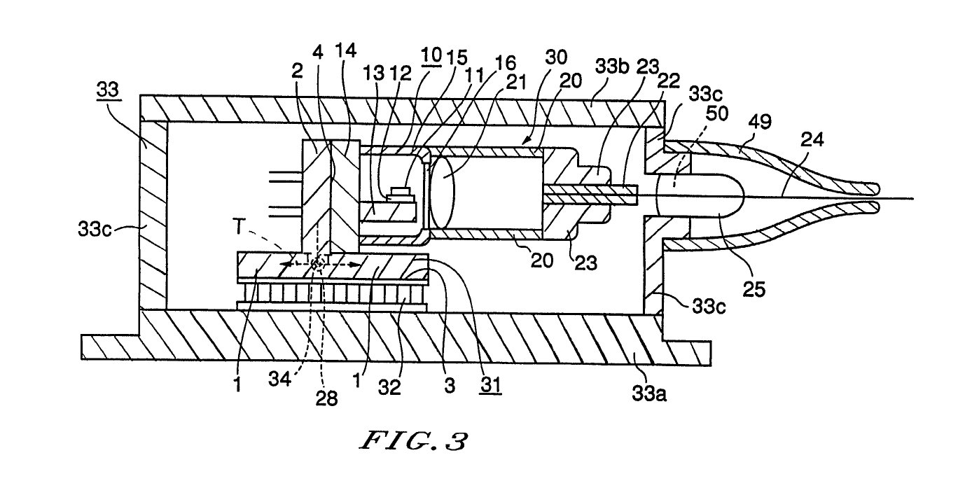

FIG. 3 is a cross-sectional view showing the construction of a semiconductor laser module in a second embodiment of the invention. The construction of the second embodiment is approximately similar to that of the first embodiment. The second embodiment differs from the first embodiment in that the stem supporting portion 2 of the base 31 is arranged approximately in a central portion of the basic portion 1.

Since the second embodiment is constructed as mentioned above, heat transmitted to the basic portion 1 through the stem supporting portion 2 is widened on both left-hand and right-hand sides of FIG. 3 and is transmitted as shown by an arrow T of FIG. 3 by arranging the stem supporting portion 2 approximately in the central portion of the basic portion 1 of the base 31. Thus, the heat can be easily widened in a direction of the face 3 (e.g., a face direction parallel to a face of the Peltier module 32) of the basic portion 1 fixed to the Peltier module 32, and is easily transmitted from the approximately central portion of the basic portion 1 to its end portion side.

Accordingly, in accordance with the second embodiment, the heat generated at the semiconductor laser element 11 can be transmitted further efficiently from the base 31 by the Peltier module 32, and heat radiating property can be further improved.

Furthermore, temperature control of the semiconductor laser element 11 by the Peltier module 32 can be performed further effectively. Accordingly, in accordance with the second embodiment, high output can be obtained from the semiconductor laser element 11 without increasing power consumption of the semiconductor laser element 11 and of the Peltier module 32. Therefore, it is possible to construct a semiconductor laser module able to be operated under a higher temperature environment.

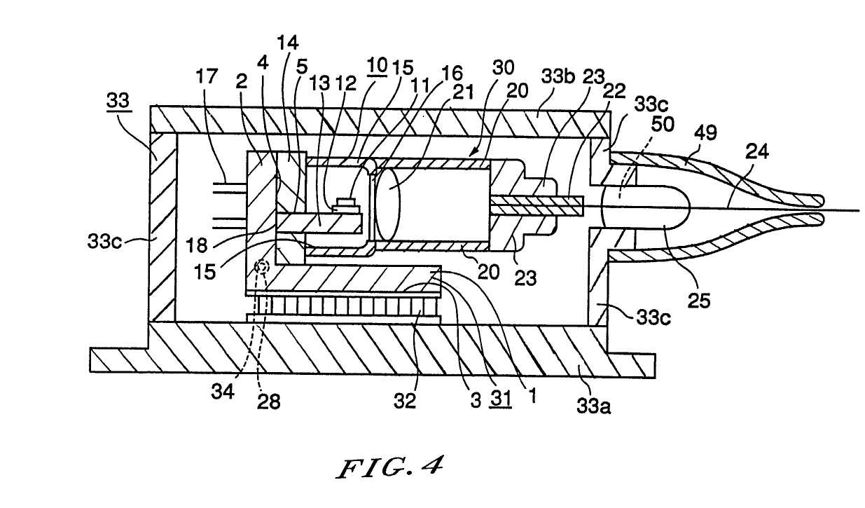

FIG. 4 is a cross-sectional view showing the construction of a semiconductor laser module in a third embodiment of the invention. The construction of the third embodiment is approximately similar to that of the first embodiment. The third embodiment differs from the first embodiment in that an element fixing block 13 extends through the stem 14, and an end face 18 of the element fixing block 13 comes in face contact with the stem supporting face 4 of the stem supporting portion 2 of the base 31.

Namely, in the third embodiment, the semiconductor laser element 11 is arranged on one end side of the element fixing block 13 fixedly extending through an opening portion of the stem 14, and the other end side of the element fixing block 13 is fixed to a through portion 5 of the stem 14, and the end face 18 of the element fixing block 13 comes in face contact with the stem supporting portion 2 of the base 31. This end face 18 is fixed to the stem supporting face 4 of the stem supporting portion 2 by, for example, an adhesive, etc.

An oscillating wavelength of the semiconductor laser element 11 is set to be 1460 mm or longer, and is also set to be 1490 nm or shorter (in a band of 1480 nm). The semiconductor laser element 11 is a light emitting element of high output and high heat generation applied for e.g., pumping of an erbium dope optical fiber. The element fixing block 13 is made of a material such as copper, a copper tungsten alloy, etc. having high thermal conductivity of 200 w/m·k or greater to ensure the sufficient radiating property of heat generated from this semiconductor laser element 11. The thermal conductivity of the element fixing block 13 is set to be greater than that of the stem 14 made of an iron-nickel alloy.

In the third embodiment, since the end face 18 of the element fixing block 13, having a thermal conductivity greater than stem 14 and extending therethrough, comes in face contact with the stem supporting portion 2 of the base 31, the heat generated at the semiconductor laser element 11 is transmitted to the stem supporting portion 2 of the base 31 sequentially through the heat sink 12 and the element fixing block 13.

Thus, in the third embodiment, the heat generated at the semiconductor laser element 11 can be almost directly transmitted from the element fixing block 13 having an excellent thermal conductivity to the base 31 without passing the stem 14. Accordingly, the conducting property of the heat generated at the semiconductor laser element 11 to the base 31 can be improved. Further, in the third embodiment, since both the element fixing block 13 and the base 31 are formed of a material having a large thermal conductivity, e.g., copper, a copper tungsten alloy, etc. the conducting property of the heat generated at the semiconductor laser element 11 to the Peltier module 32 can be improved very much, and the radiating property of this heat can be further improved.

Accordingly, in accordance with the third embodiment, with a semiconductor laser element 11 of high output with oscillating wavelength between 1460 nm and 1490 nm being used, a large amount of heat from the semiconductor laser element 11 can be radiated very efficiently, thereby enabling to keep high the performance of the semiconductor laser element 11.

In accordance with the third embodiment, a laser beam of high output in the above wavelength band can be stably outputted from the semiconductor laser element 11, by which an erbium doped optical fiber is pumped to perform optical communication of large capacity.

The invention is not limited to each of the above embodiments, but various kinds of modified embodiment can be adopted. For example, the stem supporting portion 2 is arranged on one end side of the basic portion 1 of the base 31 in the first and third embodiments, and the stem supporting portion 2 is arranged approximately on a central position of the basic portion 1 of the base 31 in the second embodiment. However, an arranging position of the stem supporting portion 2 is not specifically limited, but may be arbitrary. However, when the stem supporting portion 2 is arranged approximately on the central position of the basic portion 1 of the base 31 as in the second embodiment, heat transmitted from the stem supporting portion 2 to the basic portion 1 can be efficiently transmitted to an end portion side of the basic portion 1 so that heat radiating property can be improved.

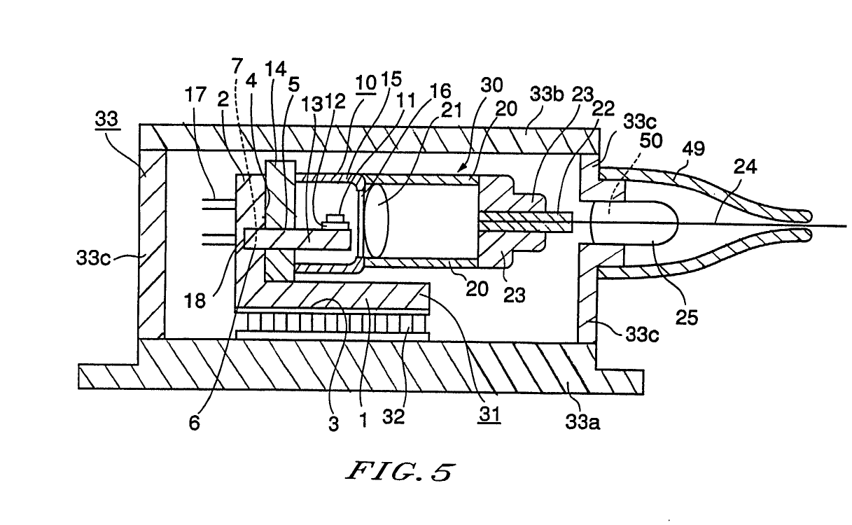

Further, in the third embodiment, a semiconductor laser element 11 is disposed on one end of the element fixing block 13 extending through the stem 14 while the other end thereof is in contact with the stem supporting portion 2 of the base 31. However, for example, as shown in FIG. 5, the other end side of the element fixing block 13 may be a projecting portion 6 projected from the stem 14. In this case, a block fitting concave portion 7 fitted to the projecting portion 6 is arranged in the stem supporting portion 2, and the projecting portion 6 of the element fixing block 13 is fitted to the block fitting concave portion 7. The projecting portion 6 is fixed to the block fitting concave portion 7 by, for example, an adhesive.

For the semiconductor laser module constructed in this way, since a contact area of the element fixing block 13 with the stem supporting portion 2 can be further increased in comparison with the third embodiment, it is possible to further improve the conducting property and the radiating property of the heat from the semiconductor laser element 11.

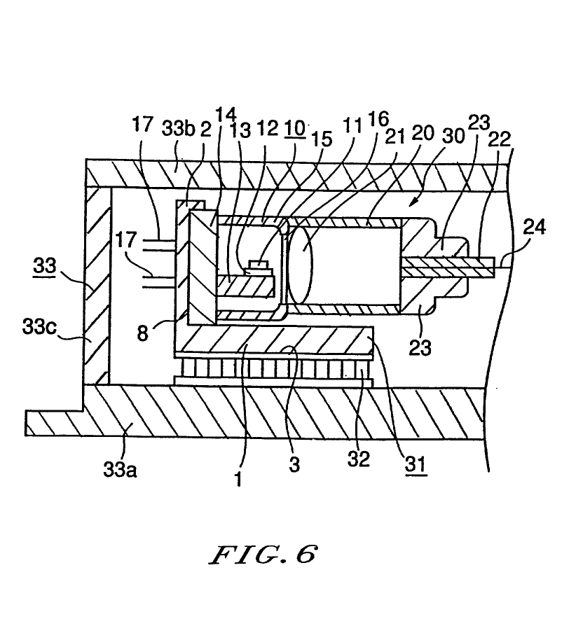

Further, in each of the above embodiments, the bottom face of the stem 14 comes in hitting contact with the stem supporting face 4 of the stem supporting portion 2 of the base 31 to which the stem 14 is fixed. However, as shown in FIG. 6, a stem fitting concave portion 8 may be arranged in the stem supporting portion 2, and the stem 14 may be fitted and fixed to the stem fitting concave portion 8. In accordance with such a construction, the internal module 30 can be fixed to the base 31 further reliably, and a contact area of the stem 14 with the stem supporting portion 2 is increased. Thereby further improving the conducting property and the radiating property of the heat generated from the semiconductor laser element 11.

Further, in each of the above embodiments, the stem supporting portion 2 of the base 31 is provided upright on the basic portion 1. However, the stem supporting portion 2 is not necessarily vertical to the basic portion 1, but may be slightly inclined.

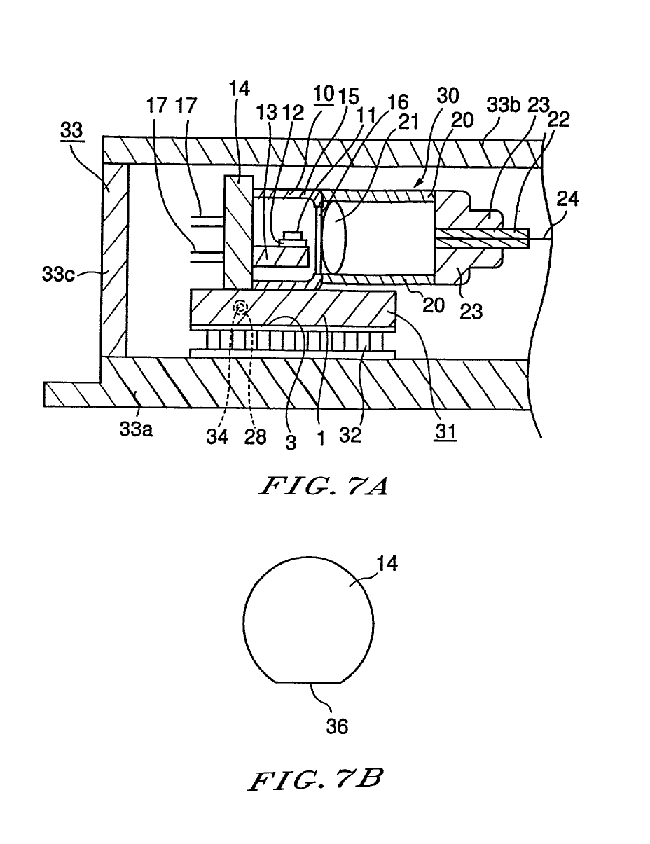

For example, as shown in FIG. 7A, it is also possible to form the base 31 by omitting the stem supporting portion 2. In this case, for example, as shown in FIG. 7B, a notch is formed on a columnar lower portion side of the stem 14 so that a lower face 36 of the stem 14 is flat. In accordance with such a construction, the stem 14 can be stably supported and fixed to the base 31 by face contact, and the conducting property of heat generated from the semiconductor laser element 11 to the base 31 can be improved.

In addition to the stem supporting portion 2 arranged on the base 31 as in the above embodiments, the flat lower face 36 of the stem 14 as shown in FIG. 7B makes it possible for stem 14 to be stably and fixedly supported to the base 31 and improve the conducting property of heat from the stem 14 to the basic portion 1 of the base 31, with a further advantage of reducing the size of the laser diode module due to the reduced thickness (reduced height from the top face of the base 31).

Further, in each of the above embodiments, the cap 15 is welded and fixed to the stem 14, and the semiconductor laser element 11 is arranged within an hermetic space formed within the cap 15. However, the cap 15 may be omitted and a lens holder 20 may be welded and fixed to the stem 14. In this case, the laser beam from the semiconductor laser element 11 can be received by the optical fiber 24 by suitably setting an arranging position of the lens 21.

Further, in each of the above embodiments, the lens 21 is arranged as an optical coupling means of the semiconductor laser element 11 and the optical fiber 24. However, for example, the optical fiber 24 may be by a spherical end fiber, etc., the end of which functions as the optical coupling means. Various kinds of optical coupling means known to those skilled in the art can be applied.

In accordance with the invention, the internal module has the semiconductor laser element attached to the stem, the optical fiber for receiving the laser beam, and the optical coupling means for coupling the laser beam to the optical fiber, and at least the stem comes in contact with the base and is fixed to the base. Accordingly, heat generated from the semiconductor laser element can be directly transmitted from the stem to the base (without passing e.g., the cap attached to the stem as in the conventional semiconductor laser module). Therefore, the heat generated in the semiconductor laser element can be efficiently transmitted to the base, and radiating property of the heat to the exterior via the base can be improved.

Accordingly, in accordance with one mode of the invention, high output of the semiconductor laser element can be obtained without causing a reduction in efficiency of the semiconductor laser element. Further, temperature control of the semiconductor laser element can be precisely performed by the Peltier module fixed to the base. Therefore, it is possible to construct a semiconductor laser module having small power consumption without causing increases in power consumption of the semiconductor laser element and of the Peltier module.

In accordance with the construction of an arrangement in which the base has the basic portion having a face fixed to the Peltier module and the stem supporting portion rising on the basic portion, and the stem is supported by the stem supporting portion in face contact with the stem, the stem comes in face contact with the stem supporting portion so that the conducting property and the radiating property of the heat can be further improved. Therefore, the power consumption of the semiconductor laser element and of the Peltier module can be further reduced, and high output can be obtained.

Further, in accordance with the invention of a construction in which the stem supporting portion is arranged approximately in a central position of the basic portion of the base, heat transmitted from the stem supporting portion of the base to the basic portion can be easily dispersed in a face direction (normally a face direction parallel to a face of the Peltier module) of the basic portion fixed to the Peltier module. The heat transmitted from the semiconductor laser element is transmitted to all parts of the base so that the heat radiating property can be further improved. Accordingly, the power consumption of each of the semiconductor laser element and the Peltier module can be further reduced so that the semiconductor laser module can be operated under a higher temperature environment.

Further, in accordance with one mode of the invention in which the stem fitting concave portion is arranged in the stem supporting portion and the stem is fitted and fixed to the stem fitting concave portion, the heat from the semiconductor laser element can be further efficiently transmitted from the stem to the base so that the radiating property of this heat can be improved. Accordingly, the power consumption of each of the semiconductor laser element and the Peltier module can be further reduced, and the stem can be more stably fixed to the base.

Further, in accordance with one mode of the invention in which the element fixing block extends through the stem and the semiconductor laser element is arranged on one end side of the element fixing block and the other end side of the element fixing block is fixed to a through portion of the stem and comes in contact with the stem supporting portion of the base, the heat generated from the semiconductor laser element can be directly transmitted from the element fixing block to the base. Therefore, it is possible to further improve the conducting property of the heat generated from the semiconductor laser element to the base and the radiating property of this heat to the exterior. Accordingly, the power consumption of each of the semiconductor laser element and the Peltier module can be further reduced, and the semiconductor laser module can be operated under a higher temperature environment.

Further, in accordance with one mode of the invention in which the other end side of the element fixing block is formed as a projecting portion projected from the stem and the block fitting concave portion fitted to the projecting portion is arranged in the stem supporting portion and the projecting portion of the element fixing block is fitted to the block fitting concave portion of the stem supporting portion, the conducting property of the heat generated from the semiconductor laser element to the base can be further improved, and the radiating property of this heat can be also improved. Accordingly, the power consumption of each of the semiconductor laser element and the Peltier module can be further reduced.

Further, heat radiating effects can be very reliably obtained by choosing a thermal conductivity of the element fixing block to be greater than that of the stem.

Further, in accordance with one mode of the invention in which a temperature sensor is arranged in the base on a path of the heat generated from the semiconductor laser element and flowing onto a Peltier module side through the base, the temperature of the semiconductor laser element can be rapidly detected by the temperature sensor, and temperature control using the Peltier module is rapidly performed on the basis of this sensed temperature.

Therefore, the temperature detection of the semiconductor laser element and a response to the temperature control are preferably made, and light output and wavelength are stabilized. Simultaneously, the power consumption of each of the semiconductor laser element and the Peltier module can be further reduced.

Further, in accordance with one mode of the invention in which the semiconductor laser element has an oscillation wavelength equal to or longer than 1460 nm and equal to or shorter than 1490 nm, the heat from the semiconductor laser element can be efficiently radiated by improving effects of the radiating property of the heat from the semiconductor laser element so that the laser beam of a high output in this wavelength band can be stably outputted. Accordingly, optical communication of large capacity, etc. can be performed by exciting an erbium dope optical fiber by this laser beam.

What is claimed is:

1. A semiconductor laser module comprising:
a package;
a Peltier module fixed to a bottom face wall of said package and accommodated into the package;
a base fixed onto said Peltier module; and
an internal module supported by said base;
said internal module having:
a stem;
a semiconductor laser element attached to said stem;
an optical fiber for guiding a laser beam emitted from said semiconductor laser element to the exterior of said package; and
optical coupling means for optically coupling the laser beam emitted from said semiconductor laser element to said optical fiber;
wherein said stem in said internal module comes in face contact with said base and is fixed to this base.

2. A semiconductor laser module according to claim 1, wherein the base has a basic portion having a face fixed to the Peltier module, and a stem supporting portion rising on the basic portion, and the stem comes in face contact with the stem supporting portion and is supported by the stem supporting portion.

3. A semiconductor laser module according to claim 2, wherein the stem supporting portion is arranged approximately in a central portion of the basic portion of the base.

4. A semiconductor laser module according to claim 2, wherein a stem fitting concave portion is arranged in the stem supporting portion, and the stem is fitted and fixed to this stem fitting concave portion.

5. A semiconductor laser module according to claim 2, wherein an element fixing block extends through an opening formed in the stem and is fixed to the stem, and the semiconductor laser element is mounted to this element fixing block, and a side face of said element fixing block extending through the opening of the stem comes in contact with the stem supporting portion of the base.

6. A semiconductor laser module according to claim 5, wherein a through tip side of the element fixing block extending through the opening of the stem is formed by a projecting portion projected from the stem, and this projecting portion is fitted to a block fitting concave portion arranged in the stem supporting portion.

7. A semiconductor laser module according to claim 5, wherein a coefficient of thermal conductivity of the element fixing block is set to be greater than that of the stem.

8. A semiconductor laser module according to claim 1, wherein a temperature sensor is arranged in the base on a path of heat generated from the semiconductor laser element and flowing onto a Peltier module side through the base.

9. A semiconductor laser module according to claim 2, wherein a temperature sensor is arranged in the base in the vicinity of an intersection point of the stem supporting portion and the basic portion.

10. A semiconductor laser module according to claim 1, wherein a stem lower face is set to a flat face and comes in face contact with the base.

11. A semiconductor laser module according to claim 1, wherein a base upper face is parallel to an optical axis of the laser beam emitted from the semiconductor laser element.

12. A semiconductor laser module according to claim 2, wherein a lead insertion hole is formed in the stem supporting portion.

13. A semiconductor laser module according to claim 1, wherein the internal module further has a heat sink and an element fixing base mounting the semiconductor laser element thereto, a cap for hermetically sealing the heat sink and the element fixing base together with the stem, and a transparent window.

14. A semiconductor laser module according to claim 1, wherein the semiconductor laser element has an oscillating wavelength equal to or greater than 1460 nm and equal to or smaller than 1490 nm.
